(19) United States
(12) Patent Application Publication
(10) Pub. No.: US 2026/0144012 A1
(43) Pub. Date: May 21, 2026

(54) Adaptive Integrated Circuit Testing Method and Adaptive Integrated Circuit Testing System Capable of Optimizing Testing Line Efficiency

(71) Applicant: MEDIATEK INC., Hsinchu City (TW)

(72) Inventors: Cheng-Tien Wan, Hsinchu City (TW); Po-Chao Tsao, Hsinchu City (TW); Wei-Lien Chen, Hsinchu City (TW); Yun-San Huang, Hsinchu City (TW); Ming-Cheng Lee, Hsinchu City (TW); Tung-Hsing Lee, Hsinchu City (TW); Chien-Fu Huang, Hsinchu City (TW); Yu-Chuan Su, Hsinchu City (TW); Jui-Ying Yang, Hsinchu City (TW); Min-Shan Huang, Hsinchu City (TW); Chia-Jung Ni, Hsinchu City (TW); Yi-Ju Ting, Hsinchu City (TW); Hung-Yu Chiou, Hsinchu City (TW); Ting-Yu Kuan, Hsinchu City (TW); Tong Wang, Beijing (CN); Yu-Lan Chang, Hsinchu City (TW); Yu-Jen Chen, Hsinchu City (TW)

(73) Assignee: MEDIATEK INC., Hsinchu City (TW)

(21) Appl. No.: 18/988,941

(22) Filed: Dec. 20, 2024

(30) Foreign Application Priority Data
Nov. 15, 2024 (CN) 202411639768.3

(51) Int. Cl. H01L 21/66

(52) U.S. Cl. CPC H10P 74/203

(57) ABSTRACT

An adaptive integrated circuit (IC) testing method includes acquiring mass production data of a plurality of ICs, analyzing the mass production data by a training model for generating predicted data of the plurality of ICs, partitioning the plurality of ICs into at least two IC groups according to the predicted data, and adjusting at least two testing processes according to the at least two IC groups. The at least two IC groups are non-overlapped.

### BACKGROUND

With the rapid advancement of technologies, various chips and integrated circuits (ICs) are adopted in our daily life. Therefore, high quality and low operational risk ICs are required for various electronic applications. In a silicon testing flow, to provide high quality and low operational risk ICs, outlier ICs are identified and labeled by analyzing measured testing data.

However, in an outlier IC identification method, some outlier ICs can be identified according to their measured testing data. Unfortunately, it is hard to predict outlier ICs since a die testing cost and a die testing time requirement are greatly increased, especially in numerous testing fields of modern multi-functional ICs.

Therefore, developing an adaptive IC testing method for predicting outlier ICs and optimizing testing line efficiency is an important design issue.

### SUMMARY

In an embodiment of the present invention, an adaptive integrated circuit (IC) testing method is disclosed. The adaptive IC testing method comprises acquiring mass production data of a plurality of ICs, analyzing the mass production data by a training model for generating predicted data of the plurality of ICs, partitioning the plurality of ICs into at least two IC groups according to the predicted data, and adjusting at least two testing processes according to the at least two IC groups. The at least two IC groups are non-overlapped.

In another embodiment of the present invention, an adaptive IC testing system is disclosed. The adaptive IC testing system comprises a mass production data source, a training model coupled to the mass production data source, and an IC grouping module coupled to the training model. The training model receives mass production data of a plurality of ICs from the mass production data source. The training model analyzes the mass production data for generating predicted data of the plurality of ICs. The IC grouping module partitions the plurality of ICs into at least two IC groups. At least two testing processes are adjusted according to the at least two IC groups. The at least two IC groups are non-overlapped.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a block diagram of an adaptive integrated circuit (IC) testing system according to an embodiment of the present invention.

FIG. 2 is an illustration of establishing a training model of the adaptive IC testing system in FIG. 1.

FIG. 3 is an illustration of introducing at least one another training model of the adaptive IC testing system in FIG. 1.

FIG. 4 is an illustration of optimizing a testing line by using the adaptive IC testing system in FIG. 1 under a first mode.

FIG. 5 is an illustration of optimizing a testing line by using the adaptive IC testing system in FIG. 1 under a second mode.

FIG. 6 is an illustration of optimizing a testing line by using the adaptive IC testing system in FIG. 1 under a third mode.

FIG. 7 is a flow chart of performing an adaptive IC testing method by the adaptive IC testing system in FIG. 1.

### DETAILED DESCRIPTION

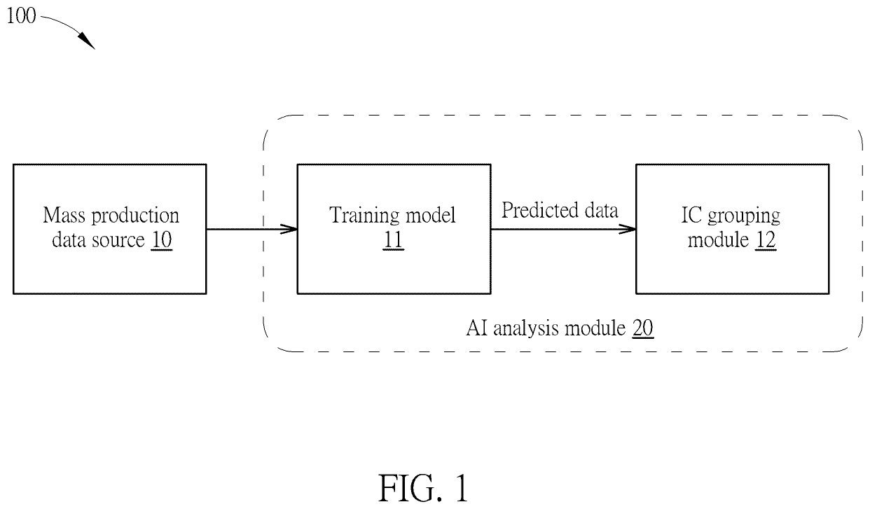

FIG. 1 is a block diagram of an adaptive integrated circuit (IC) testing system 100 according to an embodiment of the present invention. The adaptive IC testing system 100 includes a mass production data source 10, a training model 11, and an IC grouping module 12. The training model 11 is coupled to the mass production data source 10. The IC grouping module 12 is coupled to the training model 11. The mass production data source 10 can be at least one stage node of a testing line. It should be understood that the testing line can be a pre-silicon testing line. The pre-silicon testing line is a series of steps that are used for verifying the design of an integrated circuit (IC) before it is manufactured. The goal of pre-silicon testing is to identify and fix any design bugs or outlier IC before the IC is committed to silicon. In the embodiment, the mass production data source 10 is a broad term, which can include at least one of stage node of the pre-silicon testing line, such as a chip probe (CP) stage node and/or a final test (FT) stage node. The training model 11 can be saved in a memory. The IC grouping module 12 can be a processor for generating a plurality of groups of ICs. In the adaptive IC testing system 100, the training model 11 receives mass production data of a plurality of ICs from the mass production data source 10. The training model 11 can analyze the mass production data for generating predicted data of the plurality of ICs. The IC grouping module 12 partitions the plurality of ICs into at least two IC groups. At least two testing processes are adjusted according to the at least two IC groups. Here, the at least two IC groups are non-overlapped. The training model 11 and the IC grouping module 12 can form an artificial intelligence (AI) analysis module 20. The AI analysis module 20 can be applied to the testing line, such as a pre-silicon wafer testing line. Details of the adaptive IC testing system 100 are illustrated below.

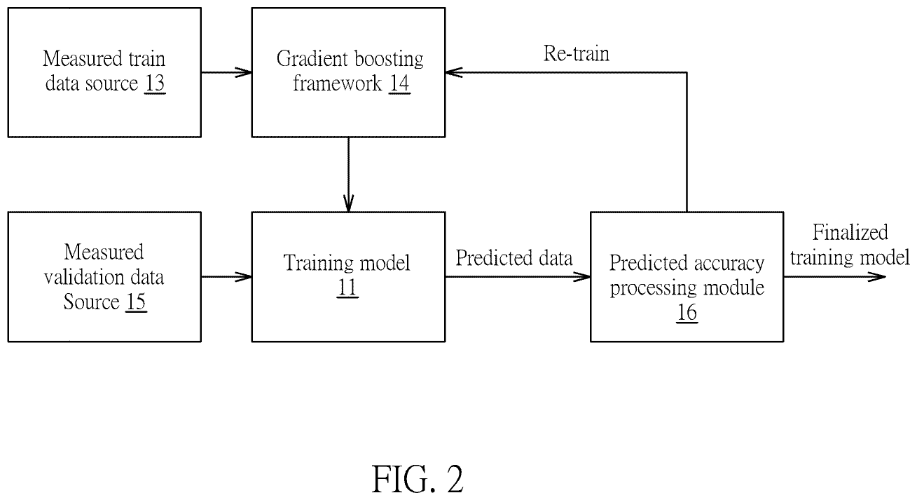

FIG. 2 is an illustration of establishing the training model 11 of the adaptive IC testing system 100. The adaptive IC testing system 100 can further include a measured train data source 13, a gradient boosting framework 14, a measured validation data source 15, and a predicted accuracy processing module 16. The gradient boosting framework 14 is coupled to the measured train data source 13 and the training model 11. The measured validation data source 15 is coupled to the training model 11. The predicted accuracy processing module 16 is coupled to the gradient boosting framework 14 and the training model 11. In the embodiment, the measured train data source 13 can be a database of measured train data previously generated. For example, the measured train data can be physical features of ICs previously measured by detectors or sensors for at least one of stage node of the pre-silicon testing line, such as measured power leakage data, measured minimum voltage (Vmin) data, process monitoring index data, and/or measured temperature data of ICs. The measured train data can be regarded as deterministic data inputted to the training model 11 for generating model's predictions. It can be understood that training a model on prepared train data (measured train data) involves adjusting the model's parameters to minimize an error between the model's predictions and actual values. In practice, the gradient boosting framework 14 can be an extreme gradient boosting (XGBoost) framework, a light gradient boosting machine (LightGBM) framework, or any gradient boosting framework for establishing the training model 11. For example, XGBoost can implement optimized gradient boosting machine learning algorithms under the Gradient Boosting framework. XGBoost is a tree-based ensemble learning algorithm that utilizes a boosting approach to achieve high performance and generalization ability. Further, it can compute gradients of the loss function with respect to the predictions of the current ensemble model. It also offers numerous parameters and options to control the training algorithm, allowing users to fine-tune the training model for specific tasks. The measured validation data source 15 can be a database of measured validation data, such as leakage data, process monitoring index data, etc. As previously mentioned, the training model 11 can be trained by adjusting the model's parameters to minimize the error between the model's predictions and actual values. Here, the measured validation data can be regarded as the actual values for validating whether the training model 11 is fully trained. In FIG. 2, the gradient boosting framework 14 establishes the training model 11 according to measured train data of the measured train data source 13. The predicted accuracy processing module 16 can determine a threshold according to a distribution centralization of quality of the plurality of ICs. For example, the predicted accuracy processing module 16 can provide a percentage threshold or a scalar threshold associating with the concentration of an IC distribution. For example, the threshold can be a variance of central tendency of an IC distribution. The predicted accuracy processing module 16 can use measured validation data of the measured validation data source 15 and the predicted data for determining if a prediction accuracy of the training model 11 has reached the threshold. When the prediction accuracy of the training model 11 reaches the threshold, it implies that the training model 11 is completely trained. For example, the threshold can be determined as the variance of the IC distribution, such as P_{TH}. According to the predicted data, when the concentration of the IC distribution is very high, it implies that the variance of the IC distribution is small enough, such as P_{V}=P_{TH}. In other words, when the variance (prediction accuracy) P_{V} reaches the threshold P_{TH}, it implies that the training model 11 is fully trained and can be available for inferring the predicted data. Therefore, the predicted accuracy processing module 16 can output the training model 11 as a finalized training model. It can be understood that the finalized training model is regarded as the fully trained training model 11. Conversely, when the prediction accuracy of the training model 11 fails to reach the threshold, it implies that the training model needs to be retrained. Therefore, the gradient boosting framework 14 can re-train the training model 11 according to the measured train data. FIG. 2 can be regarded as a structure of performing a training stage of the training model 11. After the training model 11 is completely trained, the training model 11 can be used for generating the at least two IC groups through the IC grouping module 12.

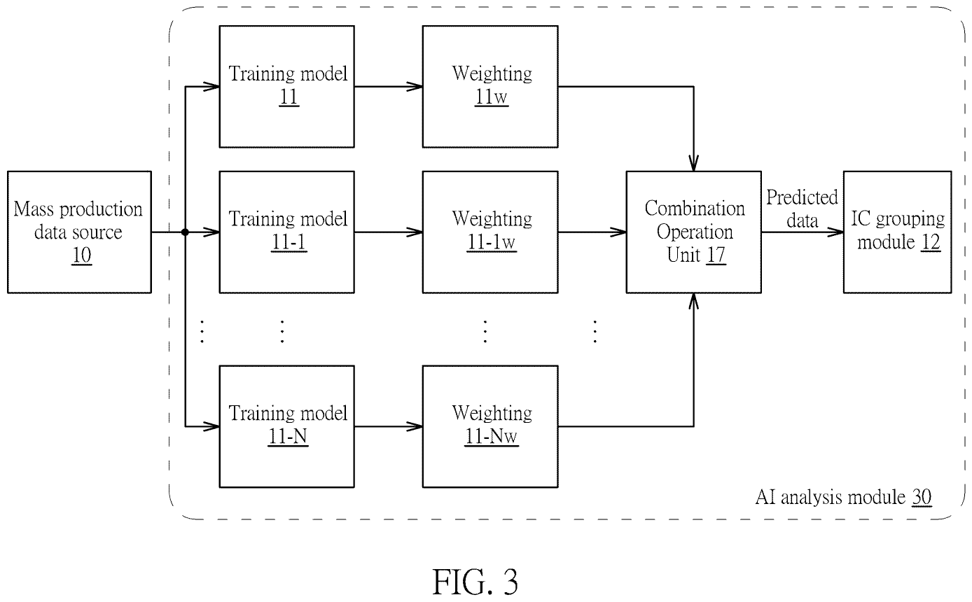

FIG. 3 is an illustration of introducing at least one another training model of the adaptive IC testing system 100. The adaptive IC testing system 100 can further include at least one additional training model coupled to the mass production data source 10. For example, the training model 11 and the training model 11-1 to the training model 11-N can be introduced to the adaptive IC testing system 100. N can be a positive integer. Here, the training model 11 and the training model 11-1 to the training model 11-N can be combined for generating the predicted data to partition the plurality of ICs according to a plurality of weightings 11w and 11-1w to 11-Nw. In FIG. 3, a combination operation unit 17 can perform a linear combination function or non-linear combination function to merge weighted outputs from the training mode 11 and training model 11-1 to the training model 11-N. In FIG. 3 the plurality of training models 11 and 11-1 to 11-N can correspond to different testing patterns of features. For example, the training mode 11 can infer (or say, output) the prediction data of power leakages of the ICs. The training mode 11-1 can infer (or say, output) the prediction data of minimum voltages of the ICs. The training mode 11-2 can infer (or say, output) the prediction data of temperatures of the ICs. Since testing terms may affect each other, introducing plurality of training modes and adjustable weightings can improve prediction accuracy. In one embodiment, scores generated by training models 11 and 11-1 to 11-N may be averaged according to corresponding weightings 11w and 11-1w to 11-Nw in a score-based strategy. In another embodiment, the training models 11 and 11-1 to 11-N can be generated “ranked scores”. Subsequently, scores generated by higher ranked training models may be averaged according to corresponding higher priority weightings in a rank-based strategy. The weightings 11w and 11-1w to 11-Nw may alternatively be configured as constant values in accordance with a standard. For example, the score-based strategy can be illustrated in Table T1, as illustrated below.

TABLE T1

| | | | | Final score |
|---|---|---|---|---|
| | | | | outputted from |
| | training | training | training | the combination |
| | model 11-1 | model 11-2 | model 11-3 | operation unit 17 |
| IC-1 | 0.8 | 0.32 | 0.29 | 0.47 |
| IC-2 | 0.26 | 0.37 | 0.4 | 0.34 |
| IC-3 | 0.91 | 0.85 | 0.22 | 0.66 |
| IC-4 | 0.65 | 0.84 | 0.52 | 0.67 |
| IC-5 | 0.03 | 0.49 | 0.18 | 0.23 |
| IC-6 | 0.06 | 0.47 | 0.04 | 0.19 |

The rank-based strategy can be illustrated in Table T2, as illustrated below.

TABLE T2

| | | | | Final score |
|---|---|---|---|---|
| | | | | outputted from the |
| | training | training | training | combination |
| | model 11-1 | model 11-2 | model 11-3 | operation unit 17 |
| IC-1 | 70 | 62 | 60 | 64.0 |
| IC-2 | 44 | 79 | 82 | 68.3 |
| IC-3 | 56 | 12 | 26 | 31.3 |
| IC-4 | 15 | 63 | 19 | 32.3 |
| IC-5 | 20 | 68 | 59 | 49.0 |
| IC-6 | 75 | 60 | 6 | 47.0 |

In the adaptive IC testing system 100, the IC groups can be generated according to the final score outputted from the combination operation unit 17. In another embodiment, when at least one criteria (score) is insufficient or smaller than a score threshold, such as score “0.03” of IC-5 and scores “0.06” and “0.04” of IC-6, the corresponding ICs are excluded as another group. For example, IC-1 to IC-4 can be categorized as a first group (say. Group-1) since their final score is greater than a threshold. IC-5 and IC-6 can be categorized as a second group (say. Group-2) since their final score is smaller than the threshold. Group generations according to the final score can be illustrated in Table T3.

TABLE T3

| | | | | Final score | |
|---|---|---|---|---|---|
| | training | training | training | outputted from the | |
| | model | model | model | combination | |
| | 11-1 | 11-2 | 11-3 | operation unit 17 | Group |
| IC-1 | 0.8 | 0.32 | 0.29 | 0.47 | Group-1 |
| IC-2 | 0.26 | 0.37 | 0.4 | 0.34 | Group-1 |
| IC-3 | 0.91 | 0.85 | 0.22 | 0.66 | Group-1 |
| IC-4 | 0.65 | 0.84 | 0.52 | 0.67 | Group-1 |
| IC-5 | 0.03 | 0.49 | 0.18 | 0.23 | Group-2 |
| IC-6 | 0.06 | 0.47 | 0.04 | 0.19 | Group-2 |

In the embodiment, when a training model is a major model for predicting data, a corresponding weighting can be increased. When a training model is a minor model for predicting data, a corresponding weighting can be decreased.

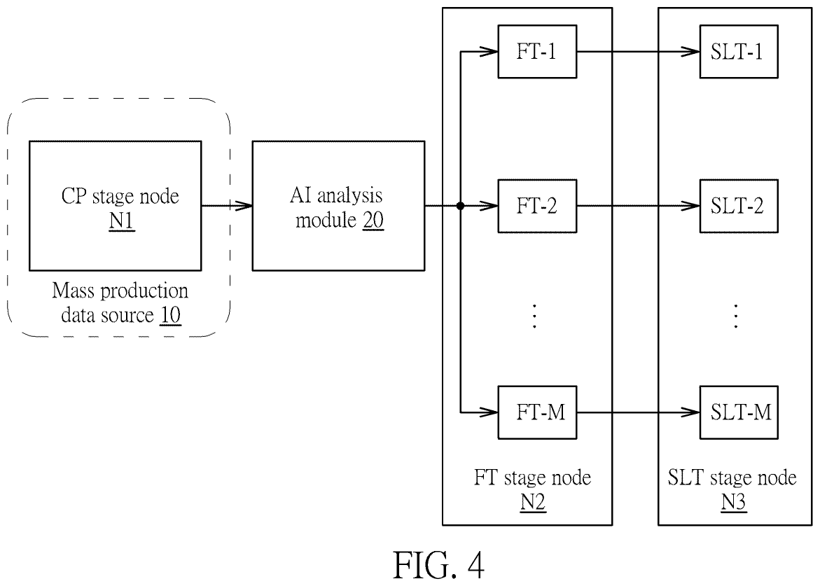

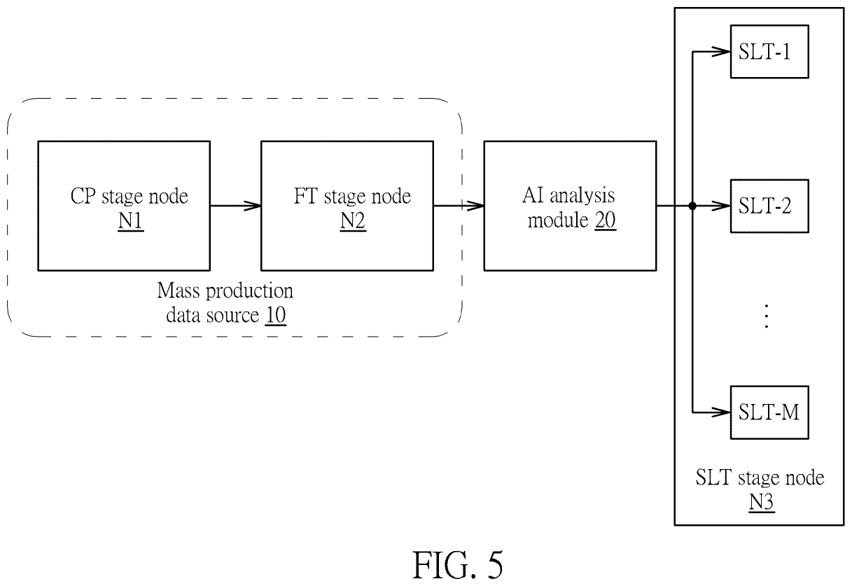

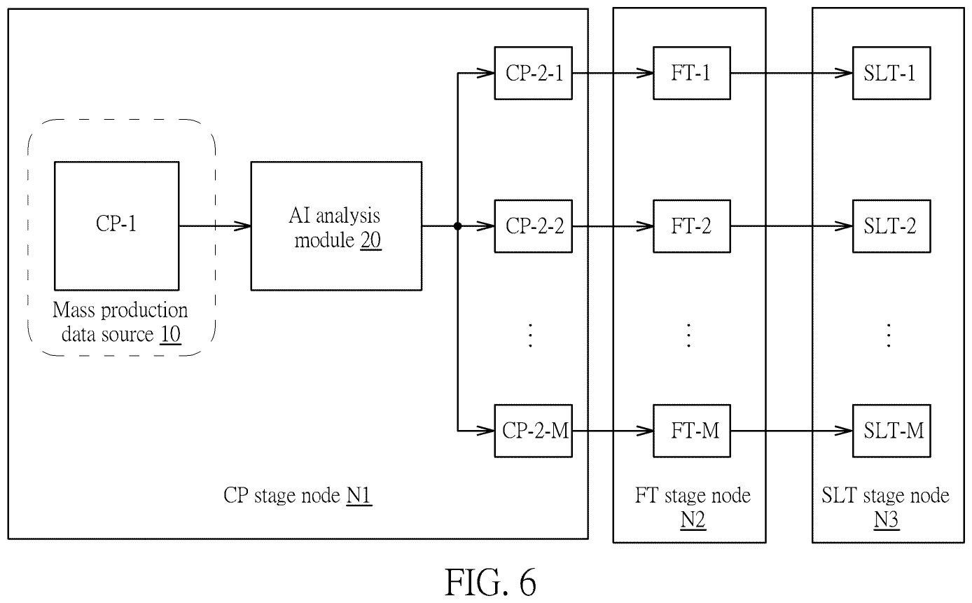

FIG. 4 is an illustration of optimizing the testing line by using the adaptive IC testing system 100 under a first mode. FIG. 5 is an illustration of optimizing the testing line by using the adaptive IC testing system 100 under a second mode. FIG. 6 is an illustration of optimizing the testing line by using the adaptive IC testing system 100 under a third mode. In FIG. 4, the mass production data source 10 can include a chip probe (CP) stage node N1 in the testing line. Therefore, the AI analysis module 20 can receive the mass production data of the plurality of ICs from the CP stage node N1 in the testing line. Then, the AI analysis module 20 can partition the plurality of ICs into at least two IC groups. In practice, the AI analysis module 20 can partition the plurality of ICs into at least two IC groups according to some primarily classified testing items of the mass production data in the CP stage node N1, such as leakage data, process monitoring index data, etc. For example, in FIG. 4, the plurality of ICs can be partitioned into a first IC group to an M-th IC group. A first testing process FT-1 of a final test (FT) stage node N2 and a first testing process SLT-1 of a system level test (SLT) stage node N3 can be adjusted according to the first IC group. A second testing process FT-2 of the FT stage node N2 and a second testing process SLT-2 of the SLT stage node N3 can be adjusted according to the second IC group. An M-th testing process FT-M of the FT stage node N2 and an M-th testing process SLT-M of the SLT stage node N3 can be adjusted according to the M-th IC group. M is a positive integer greater than two. It should be understood that differences between FT test items performed by different groups can include: (a) predicable items, such as power leakage and analog features, (b) testing efficiency improvement and cost reduction due to simplified testing items. Further, differences between SLT test items performed by different groups can include: (a) simplified system level operation test items. Therefore, since the testing processes of the FT stage node N2 and the SLT stage node N3 can be reallocated according to different IC groups, the testing line efficiency can be optimized.

In FIG. 5, the mass production data source 10 can include the CP stage node N1 or the FT stage node N2 in the testing line. Therefore, the AI analysis module 20 can receive the mass production data of the plurality of ICs from the CP stage node N1 or the FT stage node N2 in the testing line. Then, the AI analysis module 20 can partition the plurality of ICs into at least two IC groups. In practice, the AI analysis module 20 can partition the plurality of ICs into at least two IC groups according to some primarily classified testing items of the mass production data in the FT stage node N2, such as leakage data, analog features, measured minimum voltage (Vmin) data, process monitoring index data, etc. For example, in FIG. 5, the plurality of ICs can be partitioned into a first IC group to an M-th IC group. A first testing process SLT-1 of the SLT stage node N3 can be adjusted according to the first IC group. A second testing process SLT-2 of the SLT stage node N3 can be adjusted according to the second IC group. An M-th testing process SLT-M of the SLT stage node N3 can be adjusted according to the M-th IC group. Since the testing processes of the SLT stage node N3 can be reallocated according to different IC groups, the testing line efficiency can be optimized.

In FIG. 6, the mass production data source 10 includes a first part station corresponding to a first part process CP-1 of the CP stage node N1. Therefore, the AI analysis module 20 can receive the mass production data of the plurality of ICs from the first part process CP-1 of the CP stage node N1 in the testing line. Then, the AI analysis module 20 can partition the plurality of ICs into at least two IC groups. It should be understood that the CP stage node N1 can be partitioned into the first part process and second part processes since different temperatures are conditioned for testing ICs. Further, some testing items may be introduced to multiple part processes of the CP stage node N1, such as items of power leakage, memory built-in self-test (Mbist), automatic test pattern generation (ATPG), etc. In FIG. 6, the plurality of ICs can be partitioned into a first IC group to an M-th IC group. A second part process CP-2-1 of the CP stage node N1 can be adjusted according to the first IC group. A first testing process FT-1 of the FT stage node N2 and a first testing process SLT-1 of the SLT stage node N3 can be adjusted according to the first IC group. A second part process CP-2-2 of the CP stage node N1 can be adjusted according to the second IC group. A second testing process FT-2 of the FT stage node N2 and a second testing process SLT-2 of the SLT stage node N3 can be adjusted according to the second IC group. A second part process CP-2-M of the CP stage node N1 can be adjusted according to the M-th IC group. An M-th testing process FT-M of the FT stage node N2 and an M-th testing process SLT-M of the SLT stage node N3 can be adjusted according to the M-th IC group. In the embodiment, the first part process CP-1 of the CP stage node N1 can include dominating testing terms capable of predicting residue testing terms of second testing processes CP-2-1 to CP-2-M. Since the testing processes of the CP stage node N1, the FT stage node N2, and the SLT stage node N3 can be reallocated according to different IC groups, the testing line efficiency can be optimized.

In the adaptive IC testing system 100, the IC grouping module 12 can generate a testing distribution of the plurality of ICs according to the predicted data. The IC grouping module 20 can further determine a boundary (or say, a threshold) for partitioning the plurality of ICs into the at least two IC groups according to the testing distribution. In an embodiment, when one threshold is introduced, the plurality of ICs can be partitioned into a first IC group and a second IC group. As previously mentioned, different processes of at least one stage node in the pre-silicon testing line can be reallocated according to different IC groups. Details are illustrated below. When the first IC group is superior than the second IC group in quality, a complexity of a first testing process of the first IC group can be adjusted to be smaller than a complexity of a second testing process of the second IC group. For example, when the first IC group is superior than the second IC group, testing terms of the first IC group can be reduced since the first IC group has high reliability. Conversely, since the quality of the second IC group is poor, testing terms of the second IC group may be increased for identifying potential outlier ICs. In the embodiment, scaling the superiority of IC groups can used any reasonable technology. For example, given an expected testing term (such as Vmin=0.8 volts), when an average predicted Vmin of the first IC group approaches Vmin, it implies that the quality of the first IC group is satisfactory. Therefore, the complexity of a first testing process of the first IC group can be decreased. In practice, the number of testing terms of the first testing process of the first IC group can be reduced.

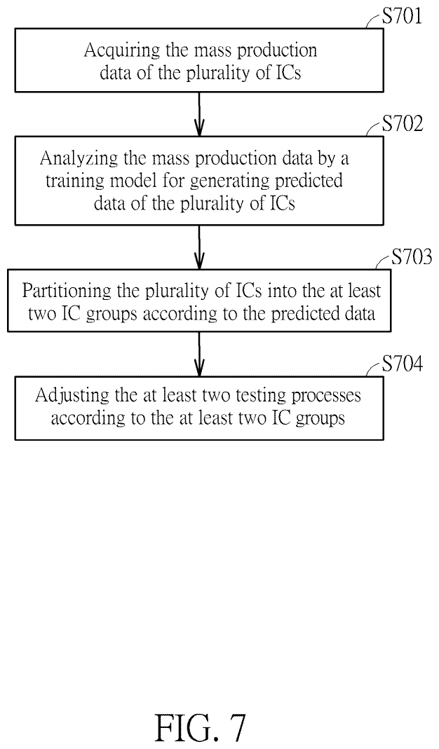

FIG. 7 is a flow chart of performing an adaptive IC testing method by the adaptive IC testing system 100. The adaptive IC testing method includes step S701 to S704. Any hardware or technology modification falls into the scope of the present invention.
step S701: acquiring the mass production data of the plurality of ICs;
step S702: analyzing the mass production data by a training model for generating predicted data of the plurality of ICs;
step S703: partitioning the plurality of ICs into the at least two IC groups according to the predicted data;
step S704: adjusting the at least two testing processes according to the at least two IC groups.

Details of step S701 to step S704 are previously illustrated. Thus, they are omitted here. In the adaptive IC testing system 100, since the plurality of ICs can be partitioned into at least two IC groups for adjusting the at least two testing processes, testing complexity and testing quality of the testing line can be optimized. Therefore, the adaptive IC testing system 100 can provide high testing quality in conjunction with low die testing cost and low testing complexity.

To sum up, the present invention discloses an adaptive IC testing system and an adaptive IC testing method. The adaptive IC testing system introduces an AI analysis module for predicting data and partitioning the plurality of ICs into at least two IC groups. The at least two IC groups can be used for adjusting subsequent testing processes in a testing line. For example, testing terms of a highly reliable IC group can be reduced. In other words, the testing complexity and testing quality of the testing line can be optimized. Therefore, the adaptive IC testing system can provide high testing quality in conjunction with low die testing cost and low testing complexity.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An adaptive integrated circuit (IC) testing method comprising:
acquiring mass production data of a plurality of ICs;
analyzing the mass production data by a training model for generating predicted data of the plurality of ICs;
partitioning the plurality of ICs into at least two IC groups according to the predicted data; and
adjusting at least two testing processes according to the at least two IC groups;
wherein the at least two IC groups are non-overlapped.

2. The method of claim 1, wherein acquiring the mass production data of the plurality of ICs, is acquiring the mass production data of the plurality of ICs from a chip probe (CP) stage node in a testing line, and wherein adjusting the at least two testing processes according to the at least two IC groups, is adjusting the at least two testing processes of a final test (FT) stage node and a system level test (SLT) stage node according to the at least two IC groups.

3. The method of claim 1, wherein acquiring the mass production data of the plurality of ICs, is acquiring the mass production data of the plurality of ICs from a final test (FT) stage node in a testing line, and wherein adjusting the at least two testing processes according to the at least two IC groups, is adjusting the at least two testing processes of a system level test (SLT) stage node according to the at least two IC groups.

4. The method of claim 1, wherein acquiring the mass production data of the plurality of ICs, is acquiring the mass production data of the plurality of ICs from a first part process of a chip probe (CP) stage node in a testing line, and wherein adjusting the at least two testing processes according to the at least two IC groups, is adjusting the at least two second part processes of the CP stage node.

5. The method of claim 1, further comprising:
generating a testing distribution of the plurality of ICs according to the predicted data; and
determining a boundary for partitioning the plurality of ICs into the at least two IC groups according to the testing distribution.

6. The method of claim 1, further comprising:
acquiring measured train data of the plurality of ICs;
using a gradient boosting framework for establishing the training model according to the measured train data;
determining a threshold according to a distribution centralization of quality of the plurality of ICs; and
using measured validation data and the predicted data for determining if a prediction accuracy of the training model reaches the threshold.

7. The method of claim 6, further comprising:
outputting the training model as a finalized training model if the prediction accuracy of the training model reaches the threshold.

8. The method of claim 6, further comprising:
re-training the training model by using a gradient boosting framework according to the measured train data if the prediction accuracy of the training model fails to reach the threshold.

9. The method of claim 1, further comprising:
establishing at least one additional training model; and
combining the training model with the at least one additional training model according to a plurality of weightings for generating the predicted data to partition the plurality of ICs.

10. The method of claim 1, wherein the at least two IC groups comprise a first IC group and a second IC group, the first IC group is superior than the second IC group in quality, a complexity of a first testing process of the first IC group is smaller than a complexity of a second testing process of the second IC group.

11. An adaptive integrated circuit (IC) testing system comprising:
a mass production data source;
a training model coupled to the mass production data source; and
an IC grouping module coupled to the training model;
wherein the training model receives mass production data of a plurality of ICs from the mass production data source, the training model analyzes the mass production data for generating predicted data of the plurality of ICs, the IC grouping module partitions the plurality of ICs into at least two IC groups, at least two testing processes are adjusted according to the at least two IC groups, and the at least two IC groups are non-overlapped.

12. The system of claim 11, wherein the mass production data source comprises a chip probe (CP) stage node in a testing line, and after the IC grouping module partitions the plurality of ICs into at least two IC groups, at least two testing processes of a final test (FT) stage node and a system level test (SLT) stage node are adjusted according to the at least two IC groups.

13. The system of claim 11, wherein the mass production data source comprises a final test (FT) stage node in a testing line, and after the IC grouping module partitions the plurality of ICs into at least two IC groups, at least two testing processes at least two testing processes of a system level test (SLT) stage node are adjusted according to the at least two IC groups.

14. The system of claim 11, wherein the mass production data source comprises a first part station corresponding to a first part process of a chip probe (CP) stage node, and after the IC grouping module partitions the plurality of ICs into at least two IC groups, at least two second part processes of the CP stage node are adjusted according to the at least two IC groups.

15. The system of claim 11, wherein the IC grouping module generates a testing distribution of the plurality of ICs according to the predicted data, and the IC grouping module determines a boundary for partitioning the plurality of ICs into the at least two IC groups according to the testing distribution.

16. The system of claim 11, further comprising:
a measured train data source;
a gradient boosting framework coupled to the measured train data source and the training model;
a measured validation data source coupled to the training model; and
a predicted accuracy processing module coupled to the gradient boosting framework and the training model;
wherein the gradient boosting framework establishes the training model according to measured train data of the measured train data source, the predicted accuracy processing module determines a threshold according to a distribution centralization of quality of the plurality of ICs, and the predicted accuracy processing module uses measured validation data of the measured validation data source and the predicted data for determining if a prediction accuracy of the training model reaches the threshold.

17. The system of claim 16, wherein the predicted accuracy processing module outputs the training model as a finalized training model if the prediction accuracy of the training model reaches the threshold.

18. The system of claim 16, wherein the gradient boosting framework re-trains the training model according to the measured train data if the prediction accuracy of the training model fails to reach the threshold.

19. The system of claim 11, further comprising:
at least one additional training model coupled to the mass production data source;
wherein after the at least one additional training model is established, the training model is combined with the at least one additional training model according to a plurality of weightings for generating the predicted data to partition the plurality of ICs.

20. The system of claim 11, wherein the at least two IC groups comprise a first IC group and a second IC group, the first IC group is superior than the second IC group in quality, a complexity of a first testing process of the first IC group is smaller than a complexity of a second testing process of the second IC group.
